(19) United States
(12) Patent Application Publication
(10) Pub. No.: US 2005/0180118 A1
(43) Pub. Date: Aug. 18, 2005

(54) Latching assembly for a removable cover of a portable electronic device

(75) Inventors: Zhen-Min Lei, Shenzhen (CN); Chia-Hua Chen, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: FIH CO., LTD, Shindian City, Taipei Hsien (TW)

(21) Appl. No.: 10/970,812

(22) Filed: Oct. 21, 2004

(30) Foreign Application Priority Data
Feb. 17, 2004 (TW) 93202227

(51) Int. Cl. H05K 5/03

(52) U.S. Cl. 361/728; 361/747

(57) ABSTRACT

A portable electronic device includes a removable panel (12), a knob (11), and a base cover (30). A latch hole (1212) is defined in the removable panel. The knob includes an operating portion (112), a shaft portion (114), and two latching members (116) protruding from the shaft portion. A latching module (20) is provided in the base cover, and two lead-in slots (244) are defined in the latching module. A hole (242, 246) is defined in the latching module. Two orienting grooves are defined in an inner wall (243, 263) of the latching module. The shaft portion of the knob extends through the latch hole of the removable panel, and the operating portion is at an upper surface (122) of the removable panel. When the operating portion is rotated, the latching members move in the orienting grooves, and the removable panel is secured to the base cover.

### CROSS-REFERENCE TO RELATED APPLICATIONS

This application is related to three copending U.S. patent applications entitled “LATCHING ASSEMBLY FOR A REMOVABLE COVER OF A PORTABLE ELECTRONIC DEVICE”, filed on the same date with the same assignee as the instant application. The disclosure of the above identified application is incorporated herein by reference.

### BACKGROUND OF THE INVENTION

1. Field of the Invention

The present invention generally relates to portable electronic devices having removable panels, and more particularly to a latching assembly for detachably securing a removable panel to a portable electronic device.

2. Prior Art

Portable electronic devices, such as mobile phones and personal digital assistants, have become widely accepted around the world. The aesthetic appearance of individual portable electronic devices has become an important requirement of many consumers. Consumers desire different appearances to satisfy their personal tastes and preferences. Thus portable electronic devices with changeable panels are especially popular.

A conventional communication device enclosure with a changeable panel is described in U.S. Pat. No. 5,848,152. The communication device includes a housing and a panel. One or more tabs extend from a periphery of the panel, and slots corresponding to the tabs are defined in a periphery of the housing. Referring to FIG. 7, a latch pin 202 extends from an inner surface of the panel, and a latch keeper 204 is defined in a rear of the housing. A first aperture 206 and a second aperture 208 are defined in the latch keeper 204, with the apertures 206, 208 being in communication with each other. When the latch pin 202 is in the first aperture 206, the panel can be released from the housing; and when the latch pin 202 is in the second aperture 208, the panel is locked on the housing. The latch keeper 204 is forcibly slid using a special tool. In assembly, the tabs of the panel are inserted into the slots of the housing, the latch pin 202 is inserted into the first aperture 206 of the latch keeper 204, and then the latch keeper 204 is slid so that the latch pin 202 enters the second aperture 208 and thereby locks the panel on the housing. In disassembly, the latch keeper 204 is slid so that the latch pin 202 enters the first aperture 206, and then the tabs of the panel are disengaged from the slots of the housing. The panel is thus removed from the housing.

However, a user needs the special tool in order to release or to lock the panel. It is not convenient to change the panel. Moreover, the latch pin is easily disengaged from the locked position when the mobile phone is jarred or dropped.

### SUMMARY OF THE INVENTION

Accordingly, an object of the present invention is to provide a latching assembly for a removable panel of a portable electronic device. The latching assembly has a relatively simple configuration which can firmly attach the removable panel to a base cover of the portable electronic device, and allow easy detachment of the removable panel from the base cover.

To achieve the above-mentioned object, an exemplary portable electronic device of the present invention includes a removable panel, a knob, and a base cover. A latch hole is defined in the removable panel. The knob includes an operating portion, a shaft portion extending downwardly from the operating portion, and a pair of latching members protruding from the shaft portion. A latching module is provided in the base cover, and a pair of lead-in slots is defined in an upper portion of the latching module. A hole is longitudinally defined in the latching module, in communication with the lead-in slots. A pair of orienting grooves is defined in an inner wall of the latching module, in communication with the lead-in slots. The shaft portion of the knob is inserted into the latch hole of the removable panel, the latching members are inserted into the lead-in holes, and the operating portion is located at an upper surface of the removable panel. When the operating portion is rotated, the latching members move in the orienting grooves, and the removable panel is secured to the base cover by engagement of the latching members with the latching module.

Other objects, advantages and novel features of the invention will become more apparent from the following detailed description when taken in conjunction with the accompanying drawings, in which:

### BRIEF DESCRIPTION OF THE DRAWINGS

FIG. 1 is an exploded, isometric view of a panel assembly and a base cover of an enclosure for a mobile phone of the present invention, the base cover comprising a latching module, the latching module comprising a first cam portion and a second cam portion;

FIG. 2 is an exploded view of FIG. 1, viewed from another aspect;

FIG. 3 is an inverted view of FIG. 2;

FIG. 4 is an enlarged, exploded isometric view of the first cam portion and the second cam portion;

FIG. 5 is an assembled view of FIG. 2;

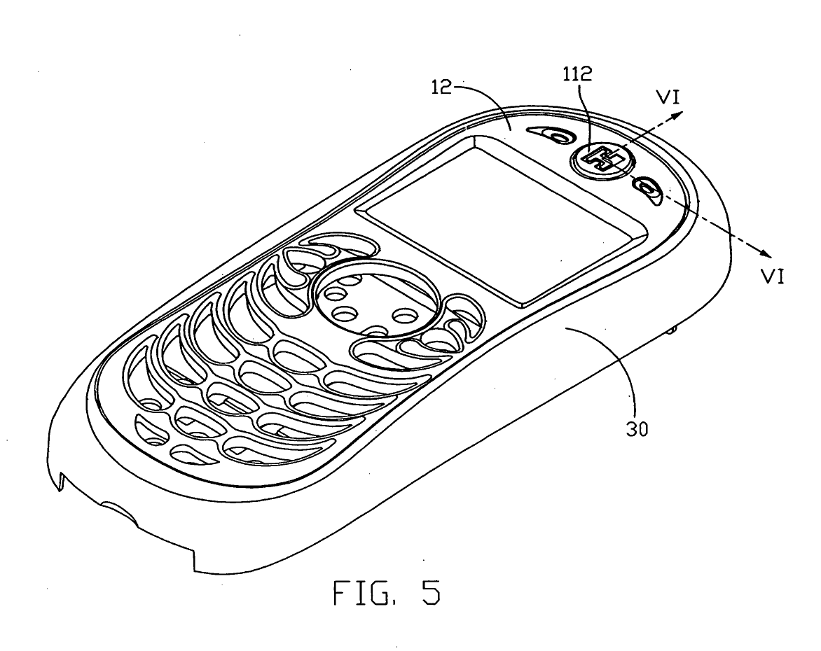

FIG. 6 is a cut-away view taken along line VI-VI of FIG. 5; and

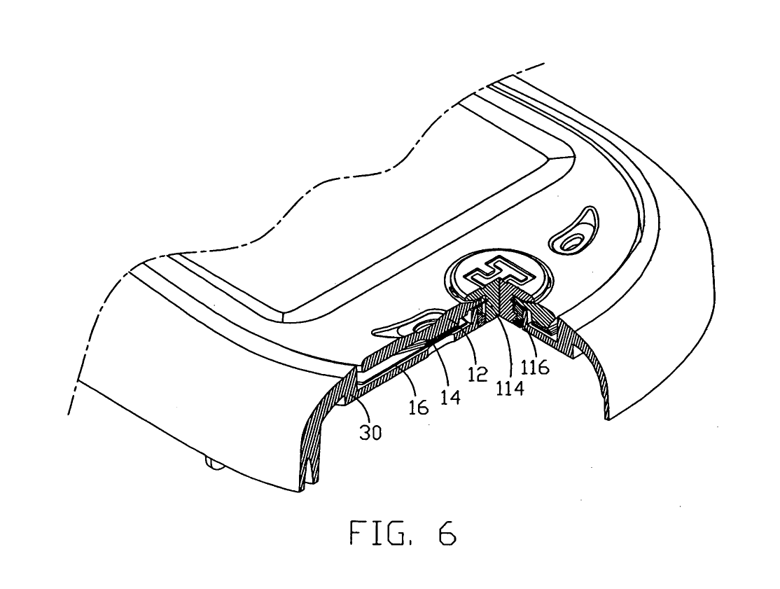

FIG. 7 is an isometric view of part of an end of an enclosure for a mobile phone of the prior art, showing a latch pin and a latch keeper thereof.

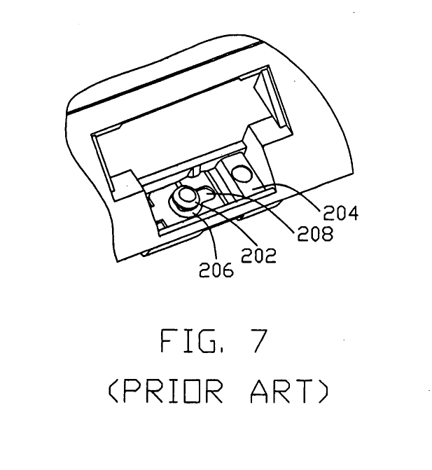

### DETAILED DESCRIPTION OF THE INVENTION

A portable electronic device in accordance with the present invention pertains to mobile phones, PDAs (Personal Digital Assistants), and like apparatuses. The present invention will be described as being embodied in a mobile phone as an illustrative example, with reference to the drawings, as follows:

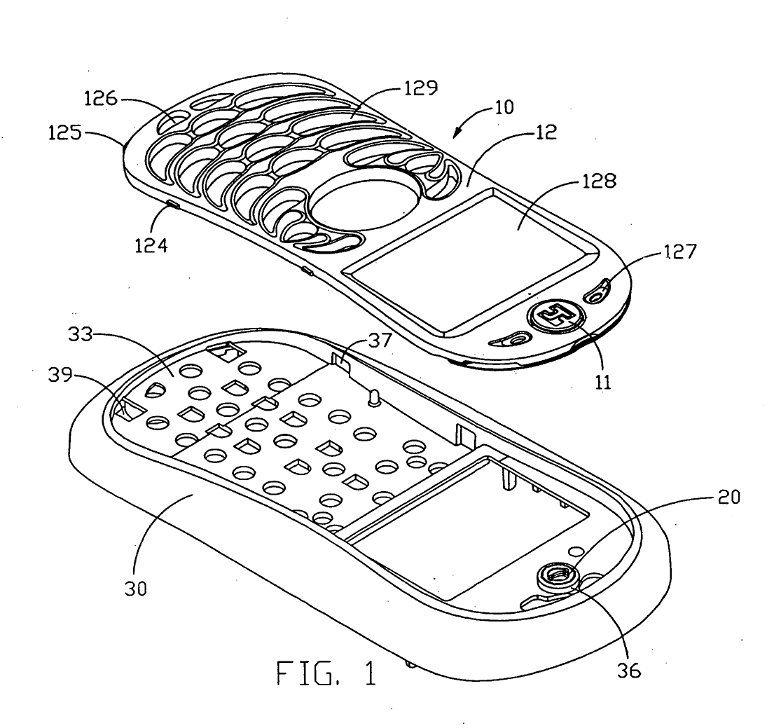

Referring to FIG. 1, an enclosure for a mobile phone includes a panel assembly 10, a latching module 20 and a base cover 30. The panel assembly 10 is attached on the base cover 30 and firmly retained thereon by way of the latching module 20. It is to be understood that the position of the latching module 20 can be varied to any other suitable location on the enclosure for the mobile phone.

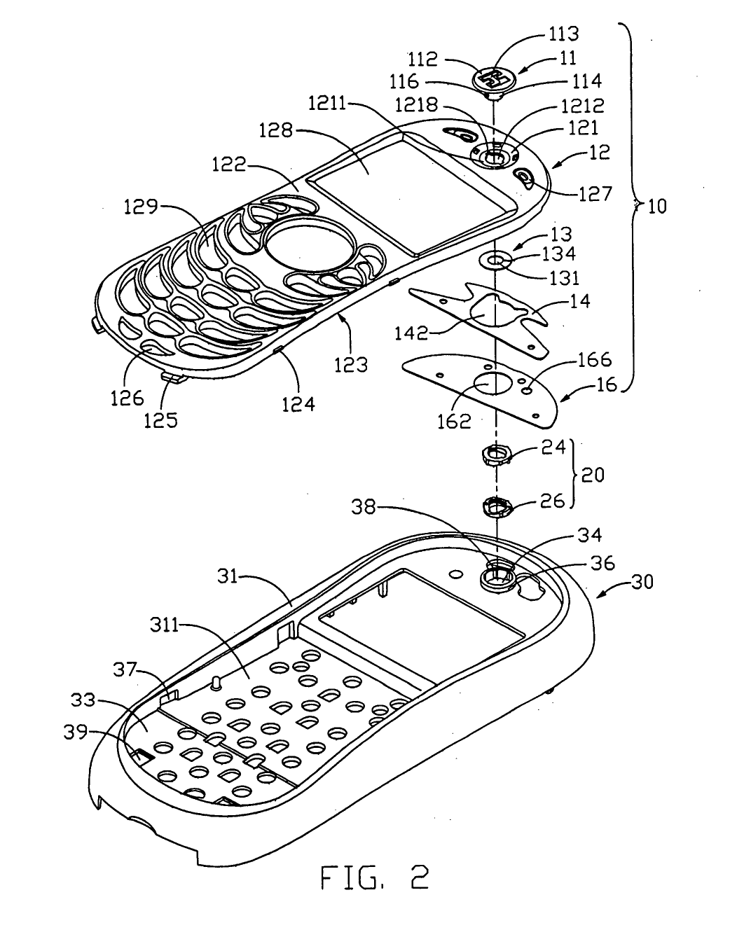

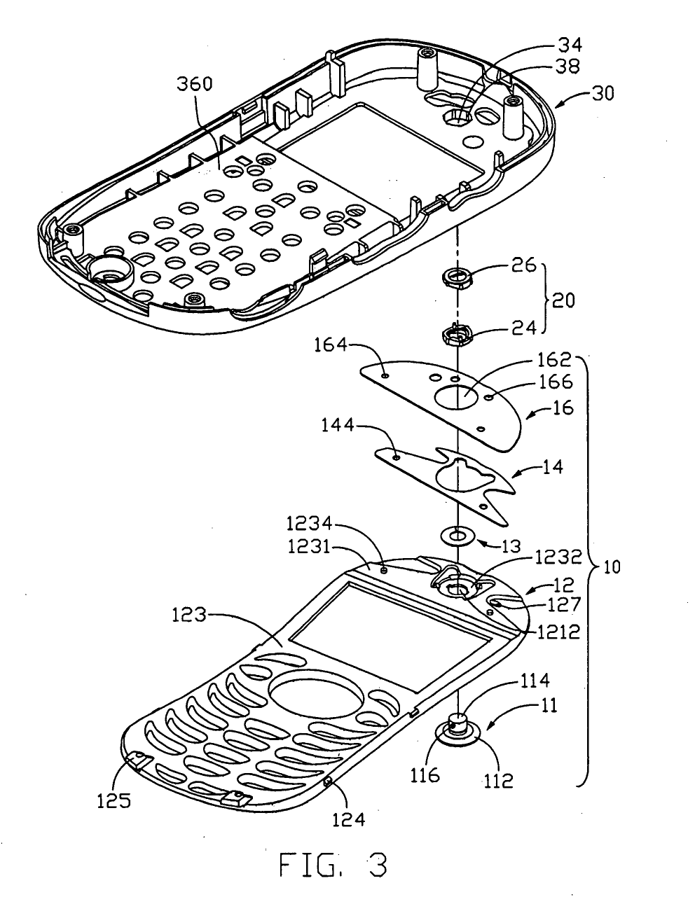

Referring also to FIGS. 2-3, the panel assembly l includes a knob 11, a removable panel 12, a ring clip 13, an adhering plate 14 and a shielding plate 16.

The knob 11 includes an operating portion 112 and a shaft portion 114. The operating portion 112 defines an H-shaped groove 113 in a topmost part thereof, for facilitating operation. The shaft portion 114 is cylindrical, and extends downwardly from the operating portion 112. Two opposite latching members 116 protrude from an end of the shaft portion 114.

The removable panel 12 includes a mounting portion 121 located in a first end thereof, an upper surface 122, a lower surface 123, a pair of detents 124 located on each of opposite long sides thereof, and two latches 125 extending from a second end thereof opposite to the first end. The removable panel 12 further includes a pair of microphone apertures 126 located in the second end thereof, a pair of speaker apertures 127 at opposite sides of the mounting portion 121 respectively, a display window 128 adjacent the mounting portion 121 and speaker apertures 127, and a plurality of keyholes 129 between the display window 128 and the microphone apertures 126. The mounting portion 121 includes a circular recess 1211 defined at the upper surface 122, a circular latch hole 1212 defined below the circular recess 1211, and two inserting holes 1218 defined at opposite sides of a peripheral edge of the latch hole 1212 respectively. The inserting holes 1218 are in communication with the latch hole 121. A recessed portion 1231 is formed at the lower surface 123 of the first end of the removable panel 12, and a shape of the recessed portion 1231 corresponds to a shape of the shielding plate 16. A depression portion 1232 is formed in a middle of the recessed portion 1231, and adjoins the mounting portion 121. Two positioning pins 1234 protrude from the recessed portion 1231 near opposite side edges of the removable panel 12 respectively. The positioning pins 1234 are used to secure the adhering plate 14 and the shielding plate 16 to the removable panel 12.

The ring clip 13 is made of a material having good elasticity. A clip hole 131 is defined in the center of the ring clip 13, a diameter of the clip hole 131 being slightly larger than a diameter of the shaft portion 114 of the knob 11. A gap 134 is defined in the ring clip 13, to enable the ring clip 13 to expand. Two opposite first and second surfaces of the adhering plate 14 are adhesive. The adhering plate 14 defines a central hole 142 corresponding to the depression portion 1232, and two opposite first positioning holes 144 for receiving the positioning pins 1234 of the recessed portion 1231. The shielding plate 16 defines a central circular hole 162 corresponding to the latch hole 1212, and two opposite second positioning holes 164 for receiving the positioning pins 1234 of the recessed portion 1231. The shielding plate 16 also defines a plurality of acoustic holes 166 therein. The shielding plate 16 is attached on the lower surface 123 of the removable panel 12 via the adhering plate 14, and shields electronic magnetic interference (“EMI”). The knob 11 is mounted in the removable panel 12 by the ring clip 13.

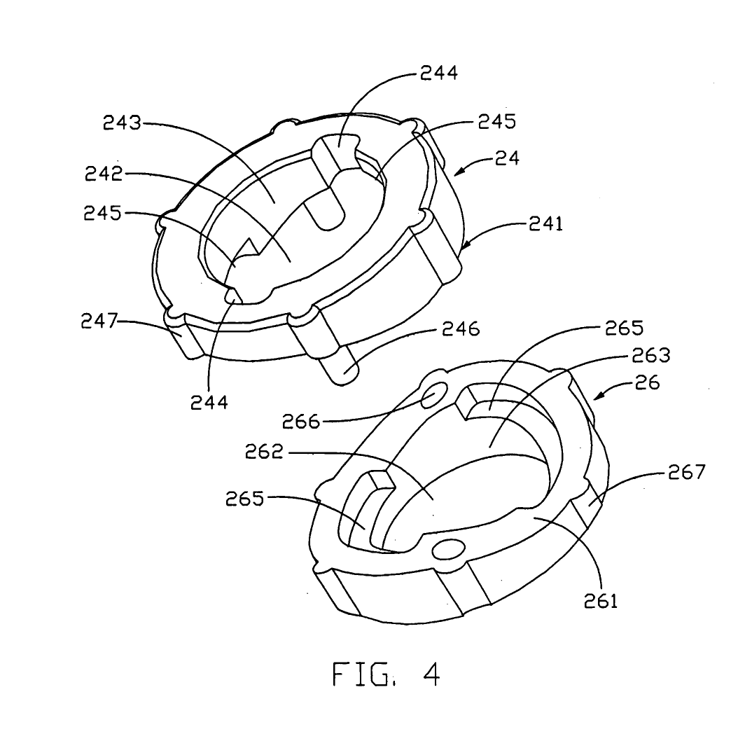

Referring to FIG. 4, the latching module 20 includes a first cam portion 24 and a second cam portion 26. The first cam portion 24 is an annular body, and defines a central first hole 242 therethrough. A first end of the first cam portion 24 has an undulating first connecting surface 241. The first connecting surface 241 includes two generally opposite mountain-shaped portions (not labeled), and two generally opposite valley-shaped portions (not labeled) between the mountain-shaped portions. Two opposite lead-in slots 244 are longitudinally defined in an inner wall 243 of the first cam portion 24 at the valley-shaped portions, in communication with the first hole 242. Two opposite first orienting slots 245 are defined in the inner wall 243 of the first cam portion 24 at the first connecting surface 241, in communication with the lead-in slots 244 to form a lead-in mechanism. The first orienting slots 245 range from the valley-shaped portions clockwise to the mountain-shaped portions. A plurality of first locating ridges 247 is formed on an outer surface of the first cam portion 24, and two opposite fitting pins 246 extend downwardly from the first connecting surface 241.

The second cam portion 26 is an annular body engaging with the first cam portion 24, and defines a central second hole 262 therethrough. A first end of the second cam portion 26 has an undulating second connecting surface 261 engaging with the first connecting surface 241. The second connecting surface 261 includes two generally opposite mountain-shaped portions (not labeled), and two generally opposite valley-shaped portions (not labeled) between the mountain-shaped portions. Two opposite second orienting slots 265 are defined in an inner wall 263 of the second cam portion 26 at the second connecting surface 261, corresponding to the first orienting slots 245. The second orienting slots 265 range from the mountain-shaped portions clockwise to the valley-shaped portions. A plurality of second locating ridges 267 is formed on an outer surface of the second cam portion 26, corresponding to the first locating ridges 247. Two opposite fitting holes 266 are defined in the second connecting surface 261, corresponding to the fitting pins 246. The first cam portion 24 and the second cam portion 26 engage with each other at the connecting surfaces 241, 261 to form the latching module 20, with the fitting pins 246 being received in the fitting holes 266. The lead-in slots 244 are at an upper surface of the assembled latching module 20. The first orienting slots 245 and the second orienting slots 246 cooperatively form a pair of orienting grooves in the inner walls 243, 263 of the latching module 20. The orienting grooves decline clockwise from the lead-in slots 244, with lowest points of the orienting grooves being at their blind ends. The first cam portion 24 and the second cam portion 26 can be fixed together at the connecting surfaces 241, 261 by ultrasonic welding, by using adhesive, or by other suitable means. It is to be understood that the latching module 20 can also be made as a single integral body having the first and second holes 242, 262, the lead-in slots 244 and the orienting grooves. For example, the latching module 20 can be formed by molding.

Referring to FIGS. 2-3 again, the base cover 30 includes a peripheral sidewall 31 and a bottom wall 33. The sidewall 31 and the bottom wall 33 cooperatively form a shallow compartment 311 in an upper portion of the base cover 30. The sidewall 31 and the bottom wall 32 also cooperatively form a receiving space 360 in a lower portion of the base cover 40, for receiving various elements of the mobile phone such as a keypad and a display. An annular mounting wall 36 is formed on a first end of the bottom wall 33. A mounting hole 34 is defined in a middle of the mounting wall 36. A plurality of mounting grooves 38 is defined in an inner surface of the mounting wall 36. The mounting grooves 38 receive the locating ridges 247, 267 of the latching module 20, for locating the latching module 20 in the mounting hole 34. A pair of detent slots 37 is defined in each of opposite long side portions of the sidewall 31, corresponding to the detents 124 of the removable panel 12. Two latch slots 39 are defined in a second end portion of the bottom wall 33, corresponding to the latches 125 of the removable panel 12. It is to be understood that the number of latches 125 and the number of latch slots 39 can be varied according to need.

In assembly, firstly, the knob 11 is attached in the removable panel 12 by the ring clip 13 as follows. The knob 21 is rotated so that the latching members 116 thereof can then be received through the inserting holes 1218. The operating portion 112 protrudes out from the circular recess 1211 of the removable panel 12. The ring clip 13 is placed around the shaft portion 114 of the knob 21, and is snapped over the latching members 116 so that the ring clip 13 is located between the removable panel 12 and the latching members 116. The gap 134 of the ring clip 13 enables the ring clip 13 to elastically expand and then recover its original shape during this process. Then the ring clip 13 is fixed on the depression portion 1232 by adhesive. The knob 11 is thus attached in the removable panel 12 by the ring clip 13. Then the adhering plate 14 is attached on the recessed portion 1231. The first positioning holes 144 of the adhering plate 14 receive the positioning pins 1234 of the recessed portion 1231, and the first surface of the adhering plate 14 adheres to the recessed portion 1231. Then the shielding plate 16 is attached on the adhering plate 14. The second positioning holes 164 of the shielding plate 16 receive the positioning pins 1234 of the recessed portion 1231, and the second surface of the adhering plate 14 adheres to the shielding plate 16. The adhering plate 14 and the shielding plate 16 are thus fixed on the removable panel 12.

Secondly, the latching module 20 is attached in the base cover 30. The latching module 20 is inserted into the mounting hole 34, with the locating ridges 247, 267 being received in the mounting grooves 38. The lead-in slots 244 are located at an upper surface of the compartment 311 of the base cover 30. The latching module 20 is then fixed in the mounting hole 34 by welding or with an adhesive.

Thirdly, the panel assembly 10 is attached to the combined base cover 30 and latching module 20. The latches 125 of the removable panel 12 are inserted into the latch slots 39 of the base cover 30. The detents 124 of the removable panel 12 are inserted into the detent slots 37 of the base cover 30. At this time, the mounting portion 121 of the removable panel 12 is positioned upon the latching module 20, and the removable panel 12 is substantially received in the compartment 311 of the base cover 30. The knob 11 is rotated until the latching members 116 are above the lead-in slots 244 of the latching module 20. The knob 11 is pressed down slightly, so that the latching members 116 are inserted into the lead-in slots 244. The knob 11 is rotated clockwise, with the latching members 116 moving in the orienting grooves. Because the orienting grooves decline clockwise, the knob 11 moves down slightly during such rotation. When the knob 21 has been rotated about 90 degrees, the latching members 116 reach the blind ends of the orienting grooves, and the operating portion 112 is received in the circular recess 1211. Thus the latching members 116 cooperate with the latching module 20 to secure the removable panel 12 to the base cover 30.

In detaching the panel assembly 10 from the base cover 30, the process is substantially the reverse of the above-described assembly process. The knob 21 is rotated counterclockwise about 90 degrees so that the latching members 116 reach the lead-in slots 244. Because the orienting grooves incline upwardly counterclockwise, the knob 11 moves up slightly during such rotation, so that the operating portion 112 protrudes from the circular recess 1211. Then the knob 11 can be gripped in order to take the removable panel 12 out from the compartment 311. Further or alternatively, the mobile phone can be inverted in order to take the removable panel 12 out from the compartment 311. The detents 124 of the removable panel 12 are released from the detent slots 37, and the latches 125 of the removable panel 12 are released from the latch slots 39.

In a further alternative embodiment, the latching module 20 can be integrally formed with the base cover 30. In particular, the first and second holes 242, 262, the lead-in slots 244 and the orienting grooves can all be formed with the base cover 30 by molding.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A portable electronic device, comprising:
a removable panel defining a latch hole therein;
a knob comprising an operating portion at an upper surface of the removable panel, a shaft portion extending downwardly from the operating portion through the latch hole, and a latching member protruding from the shaft portion; and
a base cover having a latching module, the latching module defining a central hole, an upper portion of the latching module defining a lead-in slot in communication with the central hole, an inner wall of the latching module defining an orienting groove in communication with the lead-in slot;
wherein the latching member is inserted into the lead-in slot, and the operating portion is rotated so that the latching member moves in the orienting groove, thereby securing the removable panel to the base cover.

2. The portable electronic device as claimed in claim 1, wherein the removable panel defines a recess at the upper surface thereof, and the latch hole is defined below the recess.

3. The portable electronic device as claimed in claim 2, wherein the removable panel defines an inserting hole at a peripheral edge and in communication with the latch hole.

4. The portable electronic device as claimed in claim 1, wherein the latching member protrudes from an end of the shaft portion of the knob.

5. The portable electronic device as claimed in claim 1, wherein the orienting groove declines from the lead-in slot, with a lowest point of the orienting groove being at an blind end thereof.

6. The portable electronic device as claimed in claim 1, further comprising a ring clip defining a clip hole, a diameter of the clip hole being slightly larger than a diameter of the shaft portion of the knob.

7. The portable electronic device as claimed in claim 6, wherein the ring clip further defines a gap therein, for providing the ring clip with elasticity.

8. The portable electronic device as claimed in claim 7, wherein the ring clip is located between the removable panel and the latching member.

9. The portable electronic device as claimed in claim 1, wherein the latching module comprises a first cam portion and a second cam portion.

10. The portable electronic device as claimed in claim 10, wherein the first cam portion has an undulating first connecting surface with a mountain-shaped portion and a valley-shaped portion, the second cam portion has an undulating second connecting surface with a valley-shaped portion and a mountain-shaped portion, and first and second cam portions are fittingly attached together at the first and second connecting surfaces.

11. The portable electronic device as claimed in claim 10, wherein the lead-in slot is defined in an inner wall of the first cam portion.

12. The portable electronic device as claimed in claim 11, wherein the inner wall of the first cam portion at the first connecting surface defines a first orienting slot in communication with the lead-in slot, and the first orienting slot ranges from the valley-shaped portion to the mountain-shaped portion of the first cam portion.

13. The portable electronic device as claimed in claim 12, wherein an inner wall of the second cam portion at the second connecting surface defines a second orienting slot, the second orienting slot corresponding to the first orienting slot.

14. The portable electronic device as claimed in claim 13, wherein the orienting groove is cooperatively defined by the first orienting slot and the second orienting slot.

15. The portable electronic device as claimed in claim 1, wherein a bottom wall of the base cover defines a mounting hole, the mounting hole receiving the latching module.

16. The portable electronic device as claimed in claim 1, wherein the base cover defines a shallow compartment therein, the compartment receiving the removable panel.

17. The portable electronic device as claimed in claim 1, further comprising a shielding plate attached to the removable panel.

18. The portable electronic device as claimed in claim 1, wherein the removable panel comprises a display window, a plurality of keyholes, a plurality of microphone apertures, and a plurality of speaker apertures.

19. The portable electronic device as claimed in claim 1, wherein a plurality of detents is located on opposite sides of the removable panel, and the base cover defines a plurality of detent slots receiving the detents.

20. The portable electronic device as claimed in claim 1, wherein a plurality of latches is provided on the removable panel, and the base cover defines a plurality of latch slots receiving the latches.

21. A portable electronic device, comprising:
a removable panel defining a latch hole therein;
a knob comprising an operating portion at an upper surface of the removable panel, a shaft portion extending downwardly from the operating portion through the latch hole, and a latching member extending from the shaft portion; and
a base cover including a latching module, the latching module defining a hole, an upper portion of the latching module defining a lead-in slot in communication with the hole, an inner wall of the latching module defining an orienting groove in communication with the lead-in slot;
wherein the knob is rotatable between a first position in which the latching member is located at a junction of the lead-in slot and the orienting groove and the removable panel is loosely attached on the base cover, and a second position in which the latching member is located at a blind end of the orienting groove and the removable panel is firmly attached on the base cover by engagement of the latching member with the latching module.

22. A latching assembly for a removable panel of a portable electronic device, comprising:
a knob rotatably attached to said removable panel, said knob having a shaft portion extending toward said portable electronic device and engagable therewith; and a latching module formed in said portable electronic device and reachable to said shaft portion of said knob, said latching module defining a lead-in mechanism to allow said shaft portion of said knob rotatable therein during engagement of said shaft portion and said latching module, and said knob securing and moving said removable panel toward said portable electronic device after rotation thereof by means of said engagement of said shaft portion and said latching module.

23. The portable electronic device as claimed in claim 22, wherein said lead-in mechanism has a lead-in slot and an orienting groove, said lead-in slot is used to allow full insertion of said shaft portion thereinto and said orienting groove is formed to decline rotarily about said shaft portion starting from an end portion next to said lead-in slot and gradually away from said removable panel along an groove extension thereof.
